(19) United States
(12) Patent Application Publication
(10) Pub. No.: US 2025/0266260 A1
(43) Pub. Date: Aug. 21, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yusuke MIYATA, Tokyo (JP); Yuki HARAGUCHI, Tokyo (JP); Haruhiko MINAMITAKE, Tokyo (JP); Taiki HOSHI, Tokyo (JP); Shinya AKAO, Tokyo (JP); Hidenori KOKETSU, Tokyo (JP)

(73) Assignee: Mitsubishi Electric Corporation, Tokyo (JP)

(21) Appl. No.: 18/958,539

(22) Filed: Nov. 25, 2024

(30) Foreign Application Priority Data
Feb. 19, 2024 (JP) 2024-022722

(51) Int. Cl. H01L 23/498; H01L 21/768

(52) U.S. Cl. CPC H01L 21/28518; H10D 64/232; H10D 64/251; H10D 64/62

(57) ABSTRACT

An object is to provide a technology that can suppress a failure of embedding a metal layer in recesses of an alloy layer to improve the adhesive strength between the metal layer and the alloy layer. A semiconductor device includes: a semiconductor substrate; an alloy layer on the semiconductor substrate, the alloy layer containing a semiconductor material of the semiconductor substrate as a main component; and a metal layer on the alloy layer. A plurality of recesses is discretely formed in a surface of the alloy layer which is closer to the metal layer, and 90% or more of the recesses have a bowl shape which monotonously decreases as an opening width of each of the recesses proceeds to a depth portion of the recess.

### BACKGROUND OF THE INVENTION

### Field of the Invention

The present disclosure relates to a semiconductor device, and a method of manufacturing the semiconductor device.

### Description of the Background Art

For example, WO2021/246241 discloses a semiconductor device including discrete recesses in a surface of an electrode (corresponding to an alloy layer) on a semiconductor chip (corresponding to a semiconductor substrate), and a first bonding metal (corresponding to a metal layer) on the recesses. The recesses increase the adhesive strength with the first bonding metal.

The technology described in WO2021/246241 uses a unique phenomenon of a plating process to form the recesses in the surface of the alloy layer. The plating process easily forms the recesses by selectively etching an aggregate layer or by corrosion.

Since the recesses are formed in the plating process under the technology described in WO2021/246241, controlling the opening shape of each of the recesses has been difficult. When the width of the recessed opening is smaller than the width of the recessed depth portion, the metal layer is not sometimes sufficiently embedded in the recesses. This consequently produces a problem of a decrease in the adhesive strength between the metal layer and the alloy layer.

### SUMMARY

The present disclosure has an object of providing a technology that can suppress a failure of embedding a metal layer in recesses of an alloy layer to improve the adhesive strength between the metal layer and the alloy layer.

A semiconductor device according to the present disclosure includes a semiconductor substrate, an alloy layer, and a metal layer. The alloy layer is on the semiconductor substrate, the alloy layer containing a semiconductor material of the semiconductor substrate as a main component. The metal layer is on the alloy layer. A plurality of recesses is discretely formed in a surface of the alloy layer which is closer to the metal layer. 90% or more of the recesses have a bowl shape which monotonously decreases as an opening width of each of the recesses proceeds to a depth portion of the recess.

The opening width of each of the recesses monotonously decreases as the opening width proceeds to the depth portion of the recess. This can suppress a failure of embedding the metal layer in the recesses of the alloy layer. Consequently, the adhesive strength between the metal layer and the alloy layer can be improved.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic sectional view of a semiconductor device according to an embodiment;

FIGS. 2A to 2D are schematic sectional views for describing a method of manufacturing the semiconductor device according to the embodiment;

FIG. 3 is a schematic sectional view of a contact region of the semiconductor device according to the embodiment;

Each of FIGS. 4A and 4B is a cross-section transmission electron microscopy (TEM) graph of the contact region of the semiconductor device according to the embodiment;

FIG. 5 is an enlarged view of a part of FIG. 4A with dimensions;

FIGS. 6A and 6B illustrate element maps of Si and Ar, respectively; and

FIG. 7 illustrates EDX spectra of Si and Ar.

### DESCRIPTION OF THE PREFERRED EMBODIMENTS

### Embodiment

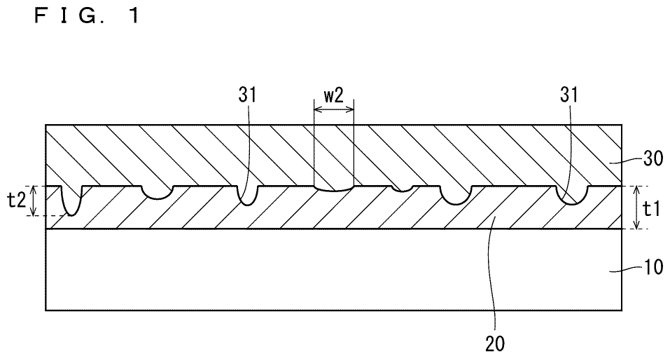

An embodiment will be hereafter described with reference to the drawings. FIG. 1 is a schematic sectional view of a semiconductor device according to the embodiment. In the following description, n and p denote semiconductor conductivity types.

As illustrated in FIG. 1, the semiconductor device is a power semiconductor device, and includes a semiconductor substrate 10, an alloy layer 20, and a metal layer 30. The alloy layer 20 is formed on the semiconductor substrate 10. The alloy layer 20 contains a semiconductor element of the semiconductor substrate 10 as a main component, and has a thickness t1. The metal layer 30 is formed on the alloy layer 20. A plurality of recesses 31 is discretely formed in the surface of the alloy layer 20 which is closer to the metal layer 30. In the following description, “the surface of the alloy layer 20 which is closer to the metal layer 30” may be simply referred to as “the surface of the alloy layer 20”.

Ninety percent or more of the recesses 31 have a bowl shape which monotonously decreases as the opening width of each of the recesses 31 proceeds to a depth portion of the recess 31. Although the cross-sectional opening width differs depending on a cut portion of the recess 31, an opening width w2 is the greatest opening width. Similarly, although the cross-sectional depth differs depending on a cut portion of the recess 31, a depth t2 is the greatest depth. Note that “monotonously decreases” indicates a shape in which the width substantially becomes narrower as the width proceeds to the depth portion of the recess. The shape may include local projections and depressions such as roughness, and should be a shape in which a boundary portion of the recesses is formed as a part of an oval in average.

A semiconductor material of the semiconductor substrate 10 may be Si, SiC, or a compound containing Ga. Furthermore, the semiconductor substrate 10 may include an n-type layer or a p-type layer in which a dopant or an acceptor is selectively activated. Furthermore, the alloy layer 20 may be in contact with the n-type layer, the p-type layer, or both of them, and may be alloyed with a semiconductor material including the n-type layer, the p-type layer, or both of them.

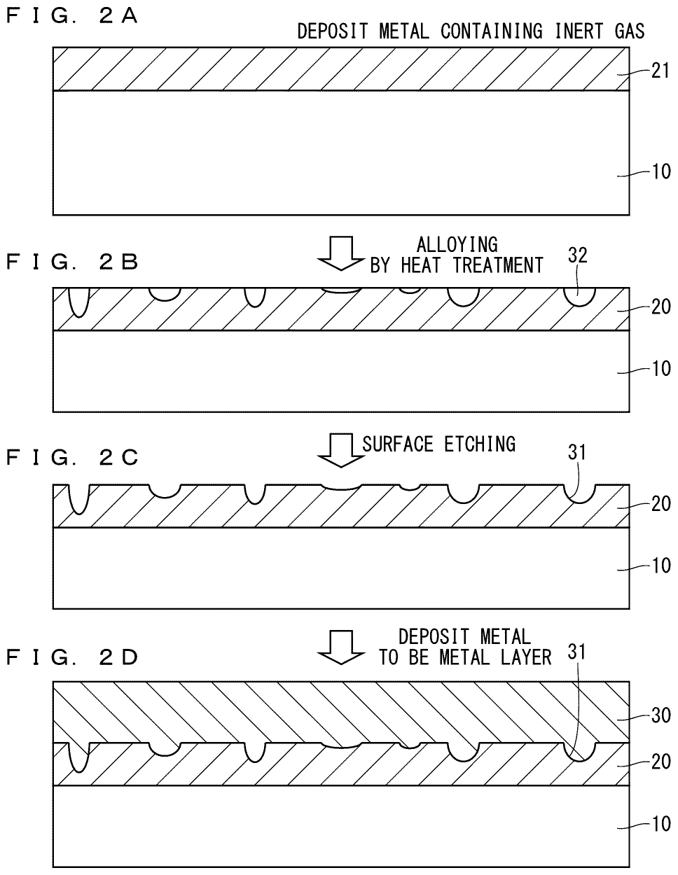

The alloy layer 20 may be formed by subjecting a metal film 21 (see FIG. 2A) to be alloyed which is deposited by sputtering or chemical vapor deposition (CVD) to a heat treatment to effect a chemical reaction of the metal film 21 to be alloyed. In this case, the alloy layer 20 contains a semiconductor element and a constituent element of the metal film 21 to be alloyed as main components. The metal film 21 to be alloyed contains, for example, Ti, Ni, or Co as a main component. The alloy layer 20 preferably has a composition containing at least 20% or more of the semiconductor material of the semiconductor substrate 10. Particularly, when the semiconductor material of the semiconductor substrate 10 is Si or SiC, the alloy layer 20 is preferably made of silicide. More preferably, the alloy layer 20 is made of silicide containing Ti or Ni.

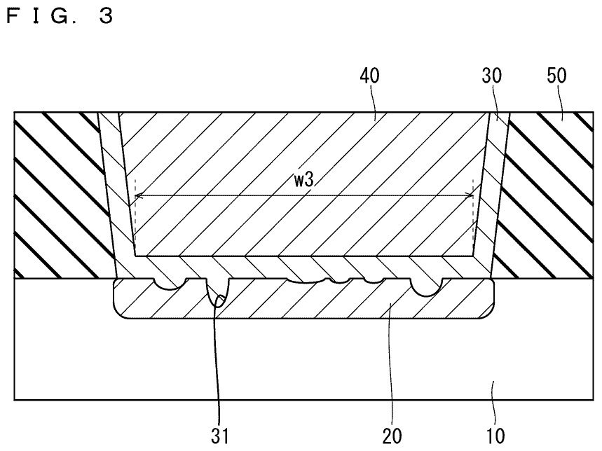

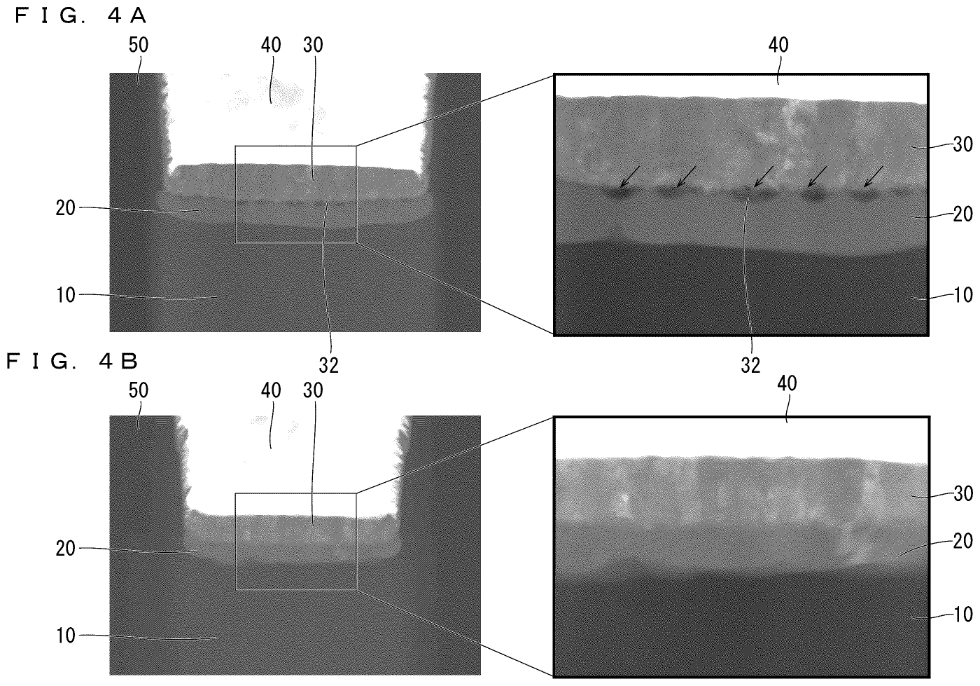

The metal layer 30 may be formed by sputtering or chemical vapor deposition (CVD). Here, the metal layer 30 may be made of Ti, Ni, W, Cu, Al or an alloy containing these. More preferably, the metal layer 30 may be made of a metal containing TiN or Al as a main component, or made of a laminated metal including a metal containing TiN as a main component and a metal containing Al as a main component. An upper metal layer 40 (see FIG. 3) with a component different from that of the metal layer 30 may be formed further on the metal layer 30.

The plurality of recesses 31 is discretely formed in the surface of the alloy layer 20, and has a shape of corroding the alloy layer 20. The thickness t1 of the alloy layer 20 is, for example, 10 nm or more and 50 nm or less. The depth t2 of the recess 31 is, for example, 5 nm or more and t1 or less. The opening width w2 of the recess 31 is, for example, 5 nm or more and 100 nm or less. The recesses 31 are filled with the metal layer 30. The recesses 31 do not include any coarse region in which an atomic density of elements contained in the alloy layer 20 or the metal layer 30 is less than 99.0 wt %. The atomic density is determined by a typical elemental analysis method such as energy-dispersive x-ray spectroscopy (EDX). In other words, the atomic density of the elements contained in the alloy layer 20 or the metal layer 30 is 99.0 wt % or more at an interface between the alloy layer 20 and the metal layer 30. This produces the anchoring effect at the interface between the alloy layer 20 and the metal layer 30, and increases the adhesive strength.

Since the recesses 31 do not include any coarse region in which the atomic density decreases, the contact resistance does not worsen. Furthermore, controlling the size of the recess 31 on the nm order can form the recesses 31 in a contact region with a width less than 1.0 μm in a power semiconductor device. Controlling the depth t2 of the recess 31 without exceeding the thickness t1 of the alloy layer 20 allows only the alloy layer 20 to be in contact with the semiconductor substrate 10, and can maintain a favorable Ohmic contact.

Next, a method of manufacturing a semiconductor device will be described. FIGS. 2A to 2D are schematic sectional views for describing the method of manufacturing a semiconductor device according to the embodiment.

As illustrated in FIG. 2A, the metal film 21 to be alloyed is formed on the semiconductor substrate 10 by depositing a metal containing an inert gas by sputtering or CVD. Next, subjecting the metal film 21 formed on the semiconductor substrate 10 to a heat treatment effects a chemical reaction of the semiconductor substrate 10 and the metal film 21 to form the alloy layer 20. Here, regions 32 of decreasing atomic densities can be formed in the surface of the alloy layer 20, by using a method described next.

An example case where the metal film 21 to be alloyed is formed by sputtering will be described. Generally, sputtering is a deposition method of filling an inert gas into a chamber at a certain rate, forming the inert gas into a plasma to cause the plasma inert gas to collide with a target metal, physically cutting bonds between atoms in the target metal to ionize (activate) metal atoms, and depositing the metal atoms on the semiconductor substrate 10. Here, the semiconductor substrate 10 contains desired metal ions but also plasma inert gas ions in trace amounts. Since the content of inert gas ions is less according to the conventional manufacturing methods, the inert gas ions are vaporized or disappear with the heat treatment, or are taken into the alloy layer 20 without condensation.

Here, when the density of the inert gas contained in the metal film 21 to be alloyed is increased, the regions 32 of decreasing atomic densities are formed in the surface of the alloy layer 20 after the heat treatment as illustrated in FIG. 2B. It is clear that the regions 32 of decreasing atomic densities have a decreasing mass percent concentration of atoms contained in the alloy layer 20 and contain a large content of the inert gas (see FIGS. 4A to 7). In other words, condensing the inert gas during the heat treatment forms a coarse region in which the atomic density decreases.

Next, as illustrated in FIG. 2C, a surface etching treatment is applied. Specifically, subjecting the surface of the alloy layer 20 including the regions 32 of decreasing atomic densities to dry etching or wet etching removes the regions 32 of decreasing atomic densities, and forms a recessed region including the plurality of recesses 31.

Next, as illustrated in FIG. 2D, depositing a metal to be the metal layer 30 on the alloy layer 20 including the recessed region produces a desired thickness of the metal layer 30, and fills the metal layer 30 in the recesses 31. Forming the recesses 31 filled with the metal layer 30 produces the anchoring effect and increases the adhesive strength. Furthermore, making the regions 32 of decreasing atomic densities disappear can suppress worsening of the contact resistance.

A phenomenon in which condensing the inert gas contained in the metal film 21 by the heat treatment forms the regions 32 of decreasing atomic densities is generally known. For example, “Inert gas bubble formation in magnetron sputtered thin-film CdTe solar cells”, Peter Hatton, et al., Proc. Of the royal soc. A, vol 476, issue 2239 describes the phenomenon. When this phenomenon is applied to a semiconductor device, the regions 32 of decreasing atomic densities can be preferably controlled each with a desired width, at a desired depth, at a desired density, and at a desired position. When the width of each of the regions 32 of decreasing atomic densities is too long, the thickness t1 of the alloy layer 20 is consequently thinned because the entire contact region of a power semiconductor device may be occupied by the regions 32.

Furthermore, when the depth of each of the regions 32 of decreasing atomic densities is too long, the contact between the metal layer 30 and the semiconductor substrate 10 does not create a favorable Ohmic contact, and increases the contact resistance. When an occupancy ratio of the regions 32 of decreasing atomic densities is too high, the thickness t1 of the alloy layer 20 is thinned, similarly to the case where the opening width w2 of the recess 31 is increased.

When the regions 32 of decreasing atomic densities are not formed in the surface of the alloy layer 20 and formed inside the alloy layer 20, the recesses 31 are not formed due to the surface etching treatment. Thus, it is important to control the regions 32 of decreasing atomic densities, each with a desired width, at a desired depth, at a desired density, and at a desired position.

Next, a method of controlling the regions 32 of decreasing atomic densities will be described. As described above, the regions 32 of decreasing atomic densities are formed by condensing an inert gas. In other words, it is necessary to control the amount of the inert gas contained in the metal film 21 to be alloyed. Controlling an amount of the inert gas to be taken by sputtering requires, for example, adjustment of a pressure in a chamber, adjustment of a plasma density, and adjustment of a voltage necessary to draw activated species into the semiconductor substrate 10.

The pressure in the chamber is adjusted by a flow rate of the inert gas, for example, in a range from 1 sccm to 100 sccm. One adjustment parameter of the plasma density is a DC bias, which is adjusted, for example, in a range from 1 kW to 50 kW. The voltage necessary to draw activated species is adjusted by an AC bias, for example, in a range from 1 W to 1 kW. The deposition temperature is, for example, a room temperature or higher and 500° C. or less. These parameters are adjusted so that the recesses 31 each with the bowl shape which is desired by a designer and which monotonously decreases as the opening width proceeds to the depth portion are formed. It is preferred that all the recesses 31 have the aforementioned shape. As long as 90% or more of the recesses 31 have the aforementioned shape, an increase in the adhesive strength from the anchoring effect is expected.

As the metal film 21 to be alloyed is thicker, the amount of atoms in the inert gas condensed at the interface between the metal film 21 and the semiconductor substrate 10 increases. Thus, the metal film 21 is preferably thicker. When the metal film 21 to be alloyed is too thick, the thickness of the alloy layer 20 tends to be increased to correspond to the thickness of the metal film 21 to be alloyed. In this case, the alloy layer 20 cannot be in contact with the n-type layer or the p-type layer in which impurities have been activated, and the contact resistance increases. Thus, the thickness of the alloy layer 20 is restricted to, for example, 30 nm or more and 50 nm or less.

Furthermore, the heat treatment after depositing the metal film 21 to be alloyed can be an important parameter. When the heat treatment is performed at a high temperature for a long time, accelerating the condensation of the inert gas widens the regions 32 of decreasing atomic densities too much. This increases the opening width w2 and the depth t2 of the recess 31, and becomes a factor of worsening the contact resistance because a desired shape cannot be obtained. The heat treatment conditions preferably range, for example, from 700° C. to 900° C. and from 10 seconds to 120 seconds. Control parameters on the heat treatment need to be adjusted so that the recesses 31 desired by the designer are obtained.

The metal film 21 to be alloyed may be deposited by CVD. This CVD differs from sputtering in that an inert gas is not taken during deposition of the metal film 21. After depositing the metal film 21, for example, an inert gas needs to be taken by an ion implantation method. Even when an inert gas is introduced after depositing the metal film 21, the inert gas condenses by the heat treatment, and the regions 32 of decreasing atomic densities are formed.

Here, the inert gas is Ar, N₂, or a noble gas element. The concentration of the inert gas contained at the interface between the metal layer 30 and the alloy layer 20 is preferably less than or equal to the concentration of the inert gas contained in the bulk of the semiconductor substrate 10.

Next, a structure of the contact region that is a part of the semiconductor device will be described. FIG. 3 is a schematic sectional view of the contact region of the semiconductor device according to the embodiment. The contact region is an emitter contact region or a source contact region.

As illustrated in FIG. 3, the contact region of the semiconductor device includes the semiconductor substrate 10, the alloy layer 20, the metal layer 30, the upper metal layer 40, and an interlayer insulating film 50. A plurality of recesses 31 is discretely formed in the surface of the alloy layer 20 which is closer to the metal layer 30. The interlayer insulating film 50 may be a tetraethyl orthosilicate (TEOS) film, a borophosphosilicate glass (BPSG) film, a thermal oxide film, or a laminated film of these films, and is formed to provide electrical isolation with a gate electrode (not illustrated). A bottom width w3 of the contact region is, for example, 0.2 μm or more and 1.0 μm or less of the submicrometer order. A ratio of the bottom width w3 of the contact region to the thickness of the interlayer insulating film 50, that is, the thickness of the interlayer insulating film 50 divided by the bottom width w3 of the contact region is, for example, 1.5 or more. Furthermore, the n-type layer or the p-type layer may be selectively formed in the semiconductor substrate 10, and the alloy layer 20 is preferably in contact with the n-type layer or the p-type layer.

Each of FIGS. 4A and 4B is a cross-section transmission electron microscopy (TEM) graph of the contact region of the semiconductor device according to the embodiment. FIG. 4A illustrates a cross-sectional structure to which the surface etching treatment illustrated in FIG. 2C is not applied. FIG. 4B illustrates a cross-sectional structure in which the regions 32 of decreasing atomic densities are not formed.

Here, the cross-section TEM graph in each of FIGS. 4A and 4B is a high angle annular dark-field (HAADF) image. A material made of homogeneous elements is lower in atomic density as the material is blacker. When the content of an inert gas is adjusted and the metal layer 30 is formed without an etching treatment under conditions including adjusted heat treatment conditions, the regions 32 of decreasing atomic densities are discretely formed as illustrated in FIG. 4A. Etching the surface of the alloy layer 20 including the regions 32 of decreasing atomic densities changes the regions 32 of decreasing atomic densities into the recesses 31. Then, depositing the metal layer 30 on the recesses 31 can produce the structure in FIG. 3.

When the content of an inert gas contained in the metal film 21 to be alloyed and the heat treatment conditions are insufficiently adjusted, the regions 32 of decreasing atomic densities are not formed as illustrated in FIG. 4B. Even when the alloy layer 20 in this state is subjected to the surface etching treatment, the recesses 31 cannot be formed.

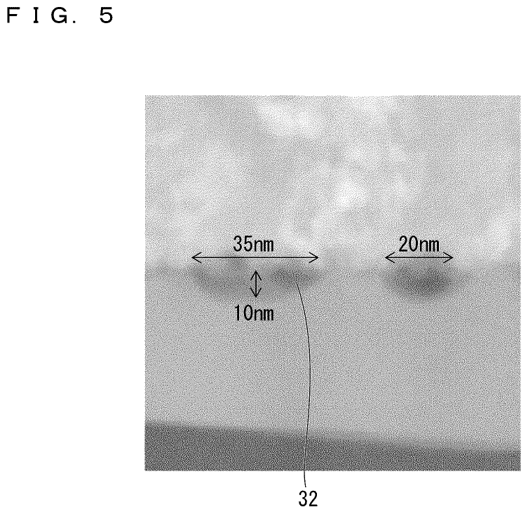

FIG. 5 is an enlarged view of a part of FIG. 4A with dimensions. As illustrated in FIG. 5, adjusting inert gas elements contained in the metal film 21 to be alloyed and the heat treatment conditions has succeeded in forming the region 32 of a decreasing atomic density with the opening width of 35 nm and the depth of 10 nm. FIG. 5 illustrates an example of this embodiment. Preferably, the opening width of the recess 31 is, for example, 5 nm or more and 100 nm or less, and the depth of the recess 31 is, for example, 5 nm or more and less than or equal to the thickness t1 of the alloy layer 20.

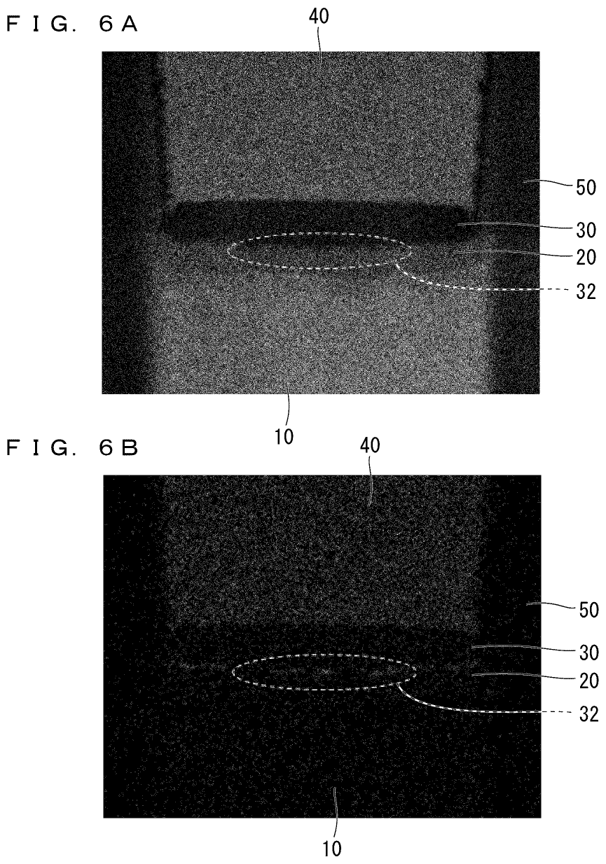

FIGS. 6A and 6B illustrate element maps of Si and Ar, respectively. Specifically, FIG. 6A illustrates an element map of Si, and FIG. 6B illustrates an element map of Ar.

Constituent elements of the metal layer 30 do not contain Si, and constituent elements of the alloy layer 20 and the semiconductor substrate 10 contain Si. Thus, the metal layer 30 is rendered in blacker contrast in the element map of Si, as illustrated in FIG. 6A. Although the upper metal layer 40 does not contain Si, EDX spectra can confirm that contrast appears in the upper metal layer 40 due to large background noise. The regions 32 of decreasing atomic densities of Si, which is a constituent element of the alloy layer 20, are formed in a region indicated by a broken line.

As illustrated in FIG. 6B, it is obvious that the atomic density of Ar in a region indicated by a broken line is high. It has been confirmed that the contrast of the upper metal layer 40 in FIG. 6B is from large background noise. An EDX spectra peak of an Ar element which is significantly higher than the background noise has been observed from the contrast of the regions 32 of decreasing atomic densities, which will be described later. Thus, the region indicated by the broken line is a region in which densities of elements that make up an alloy are smaller and an atomic concentration of an inert gas is higher.

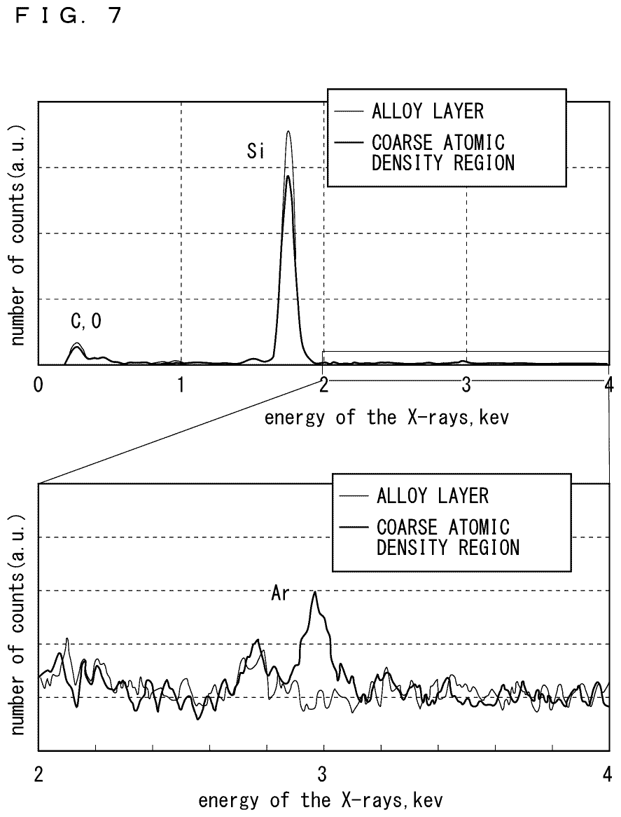

FIG. 7 illustrates the EDX spectra of Si and Ar. Specifically, an upper part in FIG. 7 illustrates EDX spectra of Si, and a lower part in FIG. 7 illustrates EDX spectra of Ar.

As illustrated in FIG. 7, thick lines represent spectra of the alloy layer 20 including the regions 32 of decreasing atomic densities, and thin lines represent spectra of the alloy layer 20 that does not include the regions 32 of decreasing atomic densities. It is obvious that the peak intensity of the semiconductor element has decreased and the Ar element can be significantly detected.

Here, the atomic density of Si in the regions 32 of decreasing atomic densities has decreased by approximately 20%. Etching the surface of the alloy layer 20 and then forming the metal layer 30 changes the regions 32 of decreasing atomic densities into the recesses 31 filled with the metal layer 30 and do not exhibit any decrease in the atomic density as illustrated in FIG. 7. Thus, the decreasing amount of atoms at the interface which is expressed by a mass percent concentration (wt %) calculated from the EDX spectra is probably less than 1.0% at maximum.

As described above, the semiconductor device according to the embodiment includes: the semiconductor substrate 10; the alloy layer 20 on the semiconductor substrate 10, the alloy layer 20 containing a semiconductor material of the semiconductor substrate 10 as a main component; and the metal layer 30 on the alloy layer 20. The plurality of recesses 31 is discretely formed in a surface of the alloy layer 20 which is closer to the metal layer 30, and 90% or more of the recesses 31 have a bowl shape which monotonously decreases as an opening width of each of the recesses 31 proceeds to a depth portion of the recess 31.

Since the opening width of each of the recesses 31 monotonously decreases as the opening width proceeds to the depth portion of the recess, a failure of embedding the metal layer 30 in the recesses 31 of the alloy layer 20 can be suppressed. This can improve the adhesive strength between the metal layer 30 and the alloy layer 20.

Furthermore, the opening width of each of the recesses 31 is 5 nm or more and 100 nm or less, the alloy layer 20 has a thickness of 30 nm or more, and the depth t2 of each of the recesses 31 is less than the thickness t1 of the alloy layer 20. This can suppress worsening of the contact resistance.

The concentration of the inert gas contained at the interface between the metal layer 30 and the alloy layer 20 is less than or equal to the concentration of the inert gas contained in the bulk of the semiconductor substrate 10. Thus, forming an interface that does not contain an inert gas can suppress a decrease in the adhesive strength.

Furthermore, the inert gas contained at the interface between the metal layer 30 and the alloy layer 20 and the inert gas contained in the bulk of the semiconductor substrate 10 are Ar or N₂. Thus, forming an interface that does not contain an inert gas can suppress a decrease in the adhesive strength.

Since the atomic density of the elements contained in the alloy layer 20 is 99.0 wt % or more, forming a dense film at the interface between the metal layer 30 and the alloy layer 20 can improve the adhesive strength.

Embodiments can be freely combined, and appropriately modified or omitted.

A summary of various aspects of the present disclosure will be hereinafter described as Appendixes.

### Appendix 1

A semiconductor device, comprising:
a semiconductor substrate;
an alloy layer on the semiconductor substrate, the alloy layer containing a semiconductor material of the semiconductor substrate as a main component; and
a metal layer on the alloy layer,
wherein a plurality of recesses is discretely formed in a surface of the alloy layer which is closer to the metal layer, and
90% or more of the recesses have a bowl shape which monotonously decreases as an opening width of each of the recesses proceeds to a depth portion of the recess.

### Appendix 2

The semiconductor device according to appendix 1,
wherein the opening width of each of the recesses is 5 nm or more and 100 nm or less,
the alloy layer has a thickness of 30 nm or more, and
a depth of each of the recesses is less than the thickness of the alloy layer.

### Appendix 3

The semiconductor device according to appendix 1 or 2, further comprising
an interlayer insulating film on the semiconductor substrate, the interlayer insulating film including a contact region,
wherein a bottom width of the contact region is 0.2 μm or more and 1.0 μm or less.

### Appendix 4

The semiconductor device according to appendix 3,
wherein a ratio of the bottom width of the contact region to a thickness of the interlayer insulating film is 1.5 or more.

### Appendix 5

The semiconductor device according to any one of appendixes 1 to 4,
wherein a concentration of an inert gas contained at an interface between the metal layer and the alloy layer is less than or equal to a concentration of an inert gas contained in a bulk of the semiconductor substrate.

### Appendix 6

The semiconductor device according to appendix 5,
wherein the inert gas contained at the interface between the metal layer and the alloy layer and the inert gas contained in the bulk of the semiconductor substrate are Ar or N₂.

### Appendix 7

The semiconductor device according to any one of appendixes 1 to 6,
wherein an atomic density of an element contained in the alloy layer is 99.0 wt % or more.

### Appendix 8

The semiconductor device according to any one of appendixes 1 to 7,
wherein the metal layer is made of a metal containing TiN or Al as a main component, or made of a laminated metal including a metal containing TiN as a main component and a metal containing Al as a main component.

### Appendix 9

The semiconductor device according to any one of appendixes 1 to 8,
wherein the semiconductor device is a power semiconductor device, and
the semiconductor material of the semiconductor substrate is Si, SiC, or a compound containing Ga.

### Appendix 10

The semiconductor device according to any one of appendixes 1 to 9,
wherein the alloy layer is made of silicide containing Ti or Ni.

### Appendix 11

A method of manufacturing a semiconductor device, the method comprising:
depositing a metal on a semiconductor substrate by sputtering or chemical vapor deposition to form a metal film, the metal containing an inert gas;
subjecting the metal film to a heat treatment to form an alloy layer;
forming, in a surface of the alloy layer which is opposite to the semiconductor substrate, a region of a decreasing atomic density of metal atoms containing the inert gas or semiconductor atoms;
etching the surface of the alloy layer to change the region of the decreasing atomic density into a recessed region with a plurality of recesses; and
depositing, on the alloy layer including the recessed region, a metal to be a metal layer.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor substrate;
an alloy layer on the semiconductor substrate, the alloy layer containing a semiconductor material of the semiconductor substrate as a main component; and
a metal layer on the alloy layer,
wherein a plurality of recesses is discretely formed in a surface of the alloy layer which is closer to the metal layer, and
90% or more of the recesses have a bowl shape which monotonously decreases as an opening width of each of the recesses proceeds to a depth portion of the recess.

2. The semiconductor device according to claim 1,
wherein the opening width of each of the recesses is 5 nm or more and 100 nm or less,
the alloy layer has a thickness of 30 nm or more, and
a depth of each of the recesses is less than the thickness of the alloy layer.

3. The semiconductor device according to claim 1, further comprising
an interlayer insulating film on the semiconductor substrate, the interlayer insulating film including a contact region,
wherein a bottom width of the contact region is 0.2 μm or more and 1.0 μm or less.

4. The semiconductor device according to claim 3,
wherein a ratio of the bottom width of the contact region to a thickness of the interlayer insulating film is 1.5 or more.

5. The semiconductor device according to claim 1,
wherein a concentration of an inert gas contained at an interface between the metal layer and the alloy layer is less than or equal to a concentration of an inert gas contained in a bulk of the semiconductor substrate.

6. The semiconductor device according to claim 5,
wherein the inert gas contained at the interface between the metal layer and the alloy layer and the inert gas contained in the bulk of the semiconductor substrate are Ar or N₂.

7. The semiconductor device according to claim 1,
wherein an atomic density of an element contained in the alloy layer is 99.0 wt % or more.

8. The semiconductor device according to claim 1,
wherein the metal layer is made of a metal containing TiN or Al as a main component, or made of a laminated metal including a metal containing TiN as a main component and a metal containing Al as a main component.

9. The semiconductor device according to claim 1,
wherein the semiconductor device is a power semiconductor device, and
the semiconductor material of the semiconductor substrate is Si, SiC, or a compound containing Ga.

10. The semiconductor device according to claim 1,
wherein the alloy layer is made of silicide containing Ti or Ni.

11. A method of manufacturing a semiconductor device, the method comprising:
depositing a metal on a semiconductor substrate by sputtering or chemical vapor deposition to form a metal film, the metal containing an inert gas;
subjecting the metal film to a heat treatment to form an alloy layer;
forming, in a surface of the alloy layer which is opposite to the semiconductor substrate, a region of a decreasing atomic density of metal atoms containing the inert gas or semiconductor atoms;
etching the surface of the alloy layer to change the region of the decreasing atomic density into a recessed region with a plurality of recesses; and
depositing, on the alloy layer including the recessed region, a metal to be a metal layer.
